(19) United States
(12) Patent Application Publication
(10) Pub. No.: US 2015/0198638 A1
(43) Pub. Date: Jul. 16, 2015

(54) METHOD AND DEVICE FOR ESTIMATING POWER AND/OR CURRENT OF INVERTER

(71) Applicant: ABB Oy, Helsinki (FI)

(72) Inventor: Samuli HEIKKILÄ, Helsinki (FI)

(73) Assignee: ABB Oy, Helsinki (FI)

(21) Appl. No.: 14/571,710

(22) Filed: Dec. 16, 2014

(30) Foreign Application Priority Data
Jan. 16, 2014 (EP) 14151422.4

(51) Int. Cl. G01R 21/00; G01R 25/00

(52) U.S. Cl. CPC G01R 21/006; G01R 25/00

(57) ABSTRACT

An exemplary device and method for estimating an active and/or reactive component of output power of a three-level inverter having a DC link divided into two halves by a neutral point. The device having control unit for determining a voltage ripple at the neutral point, determining a magnitude of a third harmonic component of the voltage ripple in a rotating coordinate system that rotates synchronously with an output voltage of the inverter, and calculating a component of an output current or power in the rotating coordinate system on the basis of the magnitude of the third harmonic component.

### RELATED APPLICATION(S)

This application claims priority under 35 U.S.C. §119 to European patent application no. 14151422.4 filed in Europe on Jan. 16, 2014, the content of which is hereby incorporated by reference in its entirety.

### FIELD

The present disclosure relates to estimation methods, and more particularly to estimating an active and/or reactive component of output power or current of an inverter.

### BACKGROUND INFORMATION

Controlling an inverter may involve gathering information on output current or output power. For example, a direct component and a quadrature component of an output current may be used when controlling torque and flux of an electric machine. In this context, the direct and quadrature components refer to components of a coordinate system rotating synchronously with a fundamental frequency component of an output voltage. The synchronously rotating coordinate system can be referred to as a dq-coordinate system. The direct component is in phase with the fundamental frequency component of the output voltage. The quadrature component has a 90 degree phase shift to the fundamental frequency component of the output voltage. Components of the output power in dq coordinates may be used in determining the power factor of the produced power, for example. The direct component of the output power may also be referred to as the active component. Correspondingly, the quadrature component may be referred to as the reactive component.

Determining the output current can involve the use of current sensors, such as current transducers, for measuring the current. The current sensors may be expensive and increase the costs of the system. Information on the output current may be used even when estimating output power, because output power can be calculated from the output voltage and the output current.

### SUMMARY

An exemplary method for a three-level inverter including a DC link divided into two halves by a neutral point is disclosed, the method comprising: determining a voltage ripple at the neutral point; determining a magnitude of a third harmonic component of the voltage ripple in a rotating coordinate system that rotates synchronously with an output voltage of the inverter; and calculating a component of an output current or power in the rotating coordinate system based on the magnitude of the third harmonic component.

An exemplary device for a three-level inverter having a DC link which is divided into two halves by a neutral point is disclosed, the device comprising: processing means for: determining a voltage ripple at the neutral point; determining a magnitude of a third harmonic component of the voltage ripple in a rotating coordinate system that rotates synchronously with an output voltage of the inverter; and calculating a component of an output current or power in the rotating coordinate system based on the magnitude of the third harmonic component.

### BRIEF DESCRIPTION OF THE DRAWINGS

In the following, the disclosure will be described in greater detail by means of the exemplary embodiments with reference to the attached drawing, in which

FIG. 1 illustrates a three-phase, three-level inverter supplying a load in accordance with an exemplary embodiment of the present disclosure.

### DETAILED DESCRIPTION

Exemplary embodiments of the present disclosure are directed to a method for estimating an active (e.g., direct) and/or reactive (e.g., quadrature) component of output power of a three-level inverter comprising a DC link divided into two halves by a neutral point (NP). The method is based on determining components of a third harmonic present in the voltage of the neutral point. The components of the output power may be estimated on the basis of the determined third harmonic components.

The third harmonic components, and thereby the components of the output power, may be estimated by using only DC link voltage measurements, for example the DC link voltage and NP voltage potential (or voltages over the halves of the DC link). Thus, the method may be performed without using current transducers.

The method may be used for controlling the output power directly without using any current measurements. The method may also be used for correcting estimation errors in power estimates of known methods, thereby enabling the use of cheaper current sensors.

Further, the exemplary method disclosed herein may also be used for estimating direct and quadrature components of the output current. The current components may be used for determining the flux orientation angle of an electrical machine, for example. The current components and the orientation angle may be used to control the torque and flux of the machine directly, for example. The method may also be used for improving the accuracy of a known flux observer based on torque and flux control.

Exemplary embodiments of the present disclosure describe a method for an inverter having a DC link which is divided into two halves by a neutral point. The inverter may be a three-level, three-phase inverter, for example. The DC link may incorporate two capacitors connected in series so that output phases are switched either to DC+, DC− or neutral point (NP) of the DC link, for example.

Further, exemplary embodiments of the present disclosure describes a device comprising means, such as a controller or processor configured to implement the method of the present disclosure.

The method and the device may be used for estimating an active (e.g., direct) and/or reactive (e.g., quadrature) component of output power of the inverter, for example. The power quantities may be estimated by using only DC link voltage measurements, for example the DC link voltage and NP potential (or voltages over the DC link capacitors).

With the DC link voltage measurements, exemplary methods described herein may determine a voltage ripple at the neutral point. A magnitude of a third harmonic component of the voltage ripple may then be determined in dq coordinates, e.g., in a rotating coordinate system that rotates synchronously with an output voltage of the inverter. The active and/or reactive component of an output power in the rotating coordinate system may be calculated on the basis of the magnitude of the third harmonic component.

According to an exemplary embodiment of the present disclosure, as the power is estimated on the basis of DC link voltage measurements, the exemplary method may be implemented without current transducers. Thus, it may be used as an alternative to the known methods where the inverter output power is estimated based on measured phase currents and voltages, for example.

According to another exemplary embodiment of the present disclosure, the method may be used for estimating a direct and/or quadrature component of output current of the inverter. Thus, the method may be for determining a flux orientation angle of an electrical machine, for example. The components of the current and the orientation angle may be used for directly controlling torque and flux of the machine.

Even when, according to another exemplary embodiment disclosed herein, the method includes performing a direct measurement of current (for example by using a DC shunt or by measuring phase currents) to ensure operation of circuit protections, for example, the exemplary method and device may be used for improving the accuracy of measurements. Thus, less accurate (and therefore less costly) current sensors may be used. Correspondingly, the method may also be used for improving the accuracy of a known flux-observer-based torque and flux control.

Exemplary methods of the present disclosure utilize an analysis of a third harmonic of the NP voltage. The third harmonic can increase with power taken from the DC link. The method assumes that the common-mode voltage is held at zero level, output voltage and frequency are constant and the load is in steady state.

Under these assumptions, a set of steady state equations for an NP current i_{NP} may be formed. The steady state equations may then be used for calculating third harmonic components of the NP voltage, and consequently the relationship between those components and the output power. The formulation of the steady state equations will be discussed next in more detail and with reference to an exemplary embodiment.

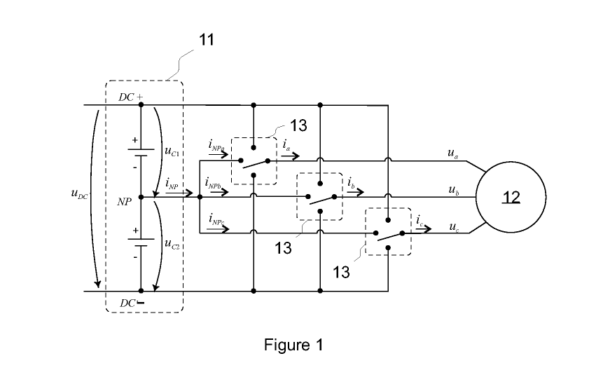

FIG. 1 shows a three-phase, three-level inverter supplying a load 12 in accordance with an exemplary embodiment of the present disclosure. The inverter includes a DC link 11 that is divided into two halves by a neutral point NP. In FIG. 1, the DC link halves are formed by two capacitances in the form of capacitors C₁ and C₂ with voltages u_{C1} and u_{C2} over them. Voltage u_{DC} represents the voltage over the whole DC link. Each of the output phases supplying the load 12 can be connected to a positive pole DC+, a negative pole DC− or the neutral point of the DC link 11 by using switching means 13.

The load 12 is supplied with phase currents iₐ, i_{b}, and i_{c} and phase voltages uₐ, u_{b}, and u_{c} in FIG. 1. A neutral point current i_{NP} flows from the neutral point NP. The neutral point current i_{NP} is divided into neutral point current phase components i_{NPa}, i_{NPb}, and i_{NPc} that flow through corresponding switching means 13.

The phase voltages uₐ, u_{b}, and u_{c} and phase currents iₐ, i_{b}, and i_{c} are assumed sinusoidal and oscillating at a fundamental frequency ω. The phase voltages uₐ, u_{b}, and u_{c} have a constant voltage amplitude U_{AMP} while the phase currents iₐ, i_{b}, and i_{c} have a constant current amplitude I_{AMP}. Thus, the phase voltages and currents may be defined in the following manner:

$$\begin{matrix}\{ \begin{matrix}{u}_{a} = {U}_{AMP} cos ( ω t ) , \\ {u}_{b} = {U}_{AMP} cos ( ω t - 2 π / 3 ) , \\ {u}_{c} = {U}_{AMP} cos ( ω t - 4 π / 3 ) ,\end{matrix} & ( 1 ) \\ \{ \begin{matrix}{i}_{a} = {I}_{AMP} cos ( ω t - ϕ ) , \\ {i}_{b} = {I}_{AMP} cos ( ω t - ϕ - 2 π / 3 ) , \\ {i}_{c} = {I}_{AMP} cos ( ω t - ϕ - 4 π / 3 ) ,\end{matrix} & ( 2 )\end{matrix}$$

where φ is a phase shift between phase voltages uₐ, u_{b}, and u_{c} and phase currents iₐ, i_{b}, and i_{c} so that φ>0 for inductive loads.

An NP voltage u_{NP} may be considered to be a voltage potential of the neutral point with respect to a virtual mid-point voltage potential between the poles of the DC link. Thus, the NP voltage u_{NP} may be considered to represent the balance of the DC link. On average, the NP voltage u_{NP} is assumed to be in balance so that u_{C1}=u_{C2}=U_{DC}/2. The ripple of the NP voltage u_{NP} is assumed to be small compared with the DC link voltage U_{DC}.

The instantaneous NP current i_{NP} may be calculated as the sum of the neutral point current phase components i_{NPa}, i_{NPb}, and i_{NPc}. Equations for the phase components i_{NPa}, i_{NPb}, and i_{NPc} may be derived from the phase currents, the phase voltages, and the DC link voltage. For example, an NP current phase component i_{NPa} of phase a is proportional to the phase current iₐ and phase voltage uₐ so that

$${i}_{NPa} = ( 1 - \frac{\vert {u}_{a} \vert}{{U}_{D C} / 2} ) {i}_{a} \qquad ( 3 )$$

In Equation (3), i_{NPa} equals iₐ when uₐ=0 (e.g., phase a is continuously connected to NP), and decreases linearly as the magnitude uₐ increases. At voltage level uₐ=±U_{DC}/2, phase a is continuously connected to one of the DC link poles and, thus, i_{NPa}=0.

Substituting Equations (1) and (2) into Equation (3) yields

$$\begin{matrix}{i}_{NPa} = ( 1 - \frac{{U}_{AMP}}{{U}_{D C} / 2} \vert cos ( ω t ) \vert ) {I}_{AMP} cos ( ω t - ϕ ) \\ = {I}_{AMP} ( 1 - 2 \frac{{U}_{AMP}}{{U}_{D C}} \vert cos ( ω t ) \vert ) ( \begin{matrix}cos ( ω t ) cos ( ϕ ) + \\ sin ( ω t ) sin ( ϕ )\end{matrix} )\end{matrix} \qquad ( 4 )$$

A real part of the third harmonic (Re₃ₕ) of the component i_{NPa} may be calculated as follows (φt→x)

$$\begin{matrix}{Re}_{3 h} \{ {i}_{NPa} \} = \frac{1}{π} {\int }_{- π}^{π} {i}_{NPa} ( x ) cos 3 x d x \\ = - 2 {I}_{AMP} \frac{{U}_{AMP}}{{U}_{D C}} ( CC cos ( ϕ ) + SC sin ( ϕ ) ) ,\end{matrix} \qquad ( 5 )$$

where

$$\{ \begin{matrix}CC = \frac{1}{π} {\int }_{- π}^{π} \vert cos x \vert cos x cos 3 x d x , \\ SC = \frac{1}{π} {\int }_{- π}^{π} \vert cos x \vert sin x cos 3 x d x = 0\end{matrix} .$$

Calculation of the definite integral CC gives:

$$\begin{matrix}CC = \frac{1}{π} {\int }_{- π}^{π} \vert cos x \vert cos x cos 3 x d x \\ = \frac{2}{π} {\int }_{- π / 2}^{π / 2} {cos}^{2} x cos 3 x d x \\ = \frac{2}{π} {\int }_{- π / 2}^{π / 2} {cos}^{2} x ( 4 {cos}^{3} x - 3 cos x ) d x \\ = \frac{2}{π} {\int }_{- π / 2}^{π / 2} ( 4 {( 1 - {sin}^{2} x )}^{2} cos x - 3 ( 1 - {sin}^{2} x ) cos x ) d x \\ = \frac{2}{π} {{\vert}^{π / 2}}_{- π / 2} ( 4 ( sin x - \frac{2}{3} {sin}^{3} x + \frac{1}{5} {sin}^{5} x ) - 3 ( sin x - \frac{1}{3} {sin}^{3} x ) ) \\ = \frac{8}{15 π} .\end{matrix}$$

SC is a definite integral of an odd function from −π to π and is therefore zero:

$$\{ \begin{matrix}CC = \frac{8}{15 π} , \\ SC = 0\end{matrix} . \qquad ( 6 )$$

Substituting Equation (6) into Equation (5) gives the real part of the third harmonic of i_{NPa}:

$${Re}_{3 h} \{ {i}_{NPa} \} = - 2 {I}_{AMP} \frac{{U}_{AMP}}{{U}_{D C}} \frac{8}{15 π} cos ( ϕ ) \qquad ( 7 )$$

Because the phase currents iₐ, i_{b}, and i_{c} have a 2π/3 phase shift between each other (e.g., i_{b}(t)=iₐ(t−2π/(3ω), i_{c}(t)=iₐ(t−4π/(3ω))) and the phase voltages uₐ, u_{b}, and u_{c} have a 2π/3 phase shift between each other (e.g., u_{b}(t)=uₐ(t−2π(3ω), and u_{c}(t)=uₐ(t−4π(3ω))), the calculation of the real part of the third harmonic of phase currents i_{NPb} and i_{NPc} yields the same coefficients as in Equation (7).

Therefore:

$${Re}_{3 h} \{ {i}_{NPa} \} = {Re}_{3 h} \{ {i}_{NPb} \} = {Re}_{3 h} \{ {i}_{NPc} \} = - M \frac{8}{15 π} {I}_{d} , \\ where \\ \{ \begin{matrix}M = \frac{{U}_{AMP}}{{U}_{D C} / 2} , \\ {I}_{d} = {I}_{AMP} cos ( ϕ )\end{matrix} . \qquad ( 8 )$$

Coefficient M represents the modulation index while I_{d} represents a direct component of the output current at the fundamental frequency of the output voltage.

The real part of the third harmonic of the NP current i_{NP} is the sum of the real parts of the third harmonics of the neutral point current phase components i_{NPa}, i_{NPb}, and i_{NPc}:

$$⇒ {Re}_{3 h} \{ {i}_{NP} \} = {Re}_{3 h} \{ {i}_{NPa} \} + {Re}_{3 h} \{ {i}_{NPb} \} + {Re}_{3 h} \{ {i}_{NPc} \} = - M \frac{8}{5 π} {I}_{d} \qquad ( 9 )$$

Correspondingly, an imaginary part of the third harmonic (Im₃ₕ) of i_{NPa} may be calculated as follows:

$${Im}_{3 h} \{ {i}_{NPa} \} = \frac{1}{π} {\int }_{- π}^{π} {i}_{NPa} ( x ) sin 3 x d x = - 2 {I}_{AMP} \frac{{U}_{AMP}}{{U}_{D C}} ( CS cos ( ϕ ) + SS sin ( ϕ ) ) , \\ where \\ \{ \begin{matrix}CS = \frac{1}{π} {\int }_{- π}^{π} \vert cos x \vert cos x sin 3 x d x = 0 , \\ SS = \frac{1}{π} {\int }_{- π}^{π} \vert cos x \vert sin x sin 3 x d x\end{matrix} . \qquad ( 10 )$$

Again, a definite integral of an odd function from −π to π− is zero and, thus, CS=0. The calculation of the definite integral SS yields:

$$\begin{matrix}SS = \frac{1}{π} {\int }_{- π}^{π} \vert cos x \vert sin x sin 3 x d x \\ = \frac{2}{π} {\int }_{- π / 2}^{π / 2} cos x sin x sin 3 x d x \\ = \frac{2}{π} {\int }_{- π / 2}^{π / 2} cos x sin x ( 3 sin x - 4 {sin}^{3} x ) d x \\ = \frac{2}{π} {\int }_{- π / 2}^{π / 2} ( 3 {sin}^{2} x - 4 {sin}^{4} x ) cos x d x \\ = \frac{2}{π} {{\vert}^{π / 2}}_{- π / 2} ( {sin}^{3} x - \frac{4}{5} {sin}^{5} x ) \\ = \frac{4}{π} ( 1 - \frac{4}{5} ) \\ = \frac{4}{5 π} .\end{matrix} \qquad$$

Thus, the imaginary part of the third harmonic of the NP current phase component i_{NPa} presented in Equation (10) may be simplified:

$${Im}_{3 h} \{ {i}_{NPa} \} = - {I}_{AMP} M \frac{4}{5 π} sin ( ϕ ) \qquad ( 11 )$$

Similarly to the real parts of phases b and c, the calculation of the imaginary parts of phases b and c yields the same coefficients as in Equation (11), and, therefore:

$${Im}_{3 h} \{ {i}_{NP} \} = 3 {Im}_{3 h} \{ {i}_{NPa} \} = - M \frac{12}{5 π} {I}_{q} , \qquad ( 12 )$$

where a quadrature component I_{q} of the current (at the fundamental frequency) may be defined as follows:

I_{q}=I_{AMP} sin(φ) (13)

Thus, the direct component I_{d} and the quadrature component I_{q} of the current at the fundamental frequency may be calculated based on the third harmonic of the NP current i_{NP} as follows:

$$\{ \begin{matrix}{I}_{d} = - \frac{5 π}{8 M} {Re}_{3 h} \{ {i}_{NP} \} , \\ {I}_{q} = - \frac{5 π}{12 M} {Im}_{3 h} \{ {i}_{NP} \}\end{matrix} . \qquad ( 14 )$$

Correspondingly, an active power component P and a reactive power component Q of the three phase system may be calculated as follows:

$$\{ \begin{matrix}P = \frac{3}{2} {U}_{AMP} {I}_{d} = - \frac{15 π}{32} {U}_{D C} {Re}_{3 h} \{ {i}_{NP} \} , \\ Q = \frac{3}{2} {U}_{AMP} {I}_{q} = - \frac{5 π}{16} {U}_{D C} {Im}_{3 h} \{ {i}_{NP} \}\end{matrix} . \qquad ( 15 )$$

A relationship between the NP current and voltage at the third harmonic frequency may be utilised in order to calculate these current and power components on the basis of the third harmonic present in the ripple of the NP voltage u_{NP}. For example in FIG. 1, an NP terminal impedance corresponds to parallel connected capacitances C₁ and C₂, which means that

$$\{ \begin{matrix}{Re}_{3 h} \{ {i}_{NP} \} = - 3 ω ( {C}_{1} + {C}_{2} ) {Im}_{3 h} \{ {u}_{NP} \} , \\ {Im}_{3 h} \{ {i}_{NP} \} = 3 ω ( {C}_{1} + {C}_{2} ) {Re}_{3 h} \{ {u}_{NP} \}\end{matrix} . \qquad ( 16 )$$

The method of the present disclosure may comprise determining the ripple in the NP voltage u_{NP} and determining a magnitude of a real and/or imaginary component of the third harmonic of the ripple in a rotating coordinate system that rotates synchronously with an output voltage of the inverter. A component or components of an output current or power in the rotating coordinate system may then be calculated on the basis of the magnitude of the third harmonic component(s).

In order to determine the voltage ripple, voltages over the halves of the DC link may be measured, and the voltage ripple may be calculated on the basis of a difference between the measured voltages. For example, in FIG. 1, the ripple of the NP voltage u_{NP} may be calculated as a difference between the lower capacitor voltage u_{C2} and the upper capacitor voltage u_{C1}:

u_{NP}=(U_{c2}−u_{C1})/2, (17)

so that Equation (16) becomes

$$\{ \begin{matrix}{Re}_{3 h} \{ {i}_{NP} \} = - \frac{3}{2} ω ( {C}_{1} + {C}_{2} ) {Im}_{3 h} \{ {u}_{C 2} - {u}_{C 1} \} , \\ {Im}_{3 h} \{ {i}_{NP} \} = \frac{3}{2} ω ( {C}_{1} + {C}_{2} ) {Re}_{3 h} \{ {u}_{C 2} - {u}_{C 1} \}\end{matrix} . \qquad ( 18 )$$

Substituting Equation (18) into Equations (14) and (15) leads to

$$\begin{matrix}\{ \begin{matrix}{I}_{d} = \frac{15 π}{16 M} ω ( {C}_{1} + {C}_{2} ) {Im}_{3 h} \{ {u}_{C 2} - {u}_{C 1} \} , \\ {I}_{q} = - \frac{5 π}{8 M} ω ( {C}_{1} + {C}_{2} ) {Re}_{3 h} \{ {u}_{C 2} - {u}_{C 1} \}\end{matrix} . & ( 19 ) \\ \{ \begin{matrix}P = \frac{45 π}{64} {U}_{D C} ω ( {C}_{1} + {C}_{2} ) {Im}_{3 h} \{ {u}_{C 2} - {u}_{C 1} \} , \\ Q = - \frac{15 π}{32} {U}_{D C} ω ( {C}_{1} + {C}_{2} ) {Re}_{3 h} \{ {u}_{C 2} - {u}_{C 1} \}\end{matrix} . & ( 20 )\end{matrix}$$

As shown in Equations (19) and (20), the DC voltages u_{C1} and u_{C2} and the third harmonic of the NP voltage carry the information used in calculating direct and quadrature current and power components at the fundamental frequency.

A direct component (for example P or I_{d}) of an output current or power in the synchronously rotating coordinate system may be estimated by determining a magnitude of a quadrature third harmonic component of the voltage ripple in the rotating coordinate system, and then by calculating the direct component (P or I_{d}) of the output current or power on the basis of the magnitude of the quadrature third harmonic component.

In a similar manner, a quadrature component (for example Q or I_{q}) of an output current or power in the synchronously rotating coordinate system may be estimated by determining a magnitude of a direct third harmonic component of the voltage ripple in the rotating coordinate system, and then by calculating the quadrature component (Q or I_{q}) of the output current or power on the basis of the magnitude of the direct third harmonic component.

According to an exemplary embodiment of the present disclosure, the method may be implemented on a control unit of an inverter, for example. The control unit may be a CPU, a DSP, an FPGA, or an ASIC, for example having programming code encoded or stored thereon to perform the method for estimating an active (e.g., direct) and/or reactive (e.g., quadrature) component of output power of a three-level inverter comprising a DC link divided into two halves by a neutral point (NP). For example, the inverter, or its control unit, may be configured to determine a voltage ripple at the neutral point, determine a magnitude of a third harmonic component of the voltage ripple in a rotating coordinate system that rotates synchronously to an output voltage of the inverter, and calculate a component of an output current or power in the rotating coordinate system on the basis of the magnitude of the third harmonic component. Control of an inverter can be based on information about the fundamental frequency and modulation index, which parameters may be readily available on the inverter. However, according to another exemplary embodiment, the device implementing the method of the present disclosure may also be a device separate from and in communication with the inverter.

According to an exemplary embodiment of the present disclosure, the method may also use the capacitance values of capacitors C₁ and C₂, which means that the current and power estimation accuracy may be directly proportional to the accuracy of these capacitances. However, the parameter accuracy only affects the magnitude of the estimated quantities so that, for example, the phase shift φ between voltage and current is completely unaffected by parameter errors when estimating it on the basis of Equation (19):

$$tan ϕ = \frac{{I}_{q}}{{I}_{d}} = - \frac{2}{3} \frac{{Re}_{3 h} \{ {u}_{C 2} - {u}_{C 1} \}}{{Im}_{3 h} \{ {u}_{C 2} - {u}_{C 1} \}} , \qquad ( 21 )$$

whereas the magnitude of the current estimate Î_{AMP} depends on the said parameters:

$${\hat{I}}_{AMP} = \frac{5 π}{8 M} ω ( {C}_{1} + {C}_{2} ) \sqrt{{Re}_{3 h} {\{ {u}_{C 2} - {u}_{C 1} \}}^{2} + \frac{9}{4} {Im}_{3 h} {\{ {u}_{C 2} - {u}_{C 1} \}}^{2 }} . \qquad ( 22 )$$

Thus, it will be appreciated by those skilled in the art that the present invention can be embodied in other specific forms without departing from the spirit or essential characteristics thereof. The presently disclosed exemplary embodiments are therefore considered in all respects to be illustrative and not restricted. The scope of the invention is indicated by the appended claims rather than the foregoing description and all changes that come within the meaning and range and equivalence thereof are intended to be embraced therein.

What is claimed is:

1. A method for a three-level inverter including a DC link divided into two halves by a neutral point, the method comprising:
determining a voltage ripple at the neutral point;
determining a magnitude of a third harmonic component of the voltage ripple in a rotating coordinate system that rotates synchronously with an output voltage of the inverter; and
calculating a component of an output current or power in the rotating coordinate system based on the magnitude of the third harmonic component.

2. The method according to claim 1, comprising:
determining a magnitude of a quadrature third harmonic component of the voltage ripple in the rotating coordinate system; and
calculating a direct component of an output current or power in the rotating coordinate system based on the magnitude of the quadrature third harmonic component.

3. The method according to claim 2, wherein a direct component of the output current is calculated by using the equation:
$${I}_{d} = \frac{15 π}{16 M} ω ( {C}_{1} + {C}_{2} ) {Im}_{3 h} \{ {u}_{C 2} - {u}_{C 1} \} ,$$
wherein ω is a fundamental frequency of the output voltage, M is the modulation index, C₁ and C₂ are capacitances forming the DC link halves, Im₃ₕ is a function for an imaginary part of a third harmonic, and u_{C1} and u_{C2} are voltages over the capacitances, respectively.

4. The method according to claim 2, wherein a direct component of the output power is calculated by using the equation:
$$P = \frac{45 π}{64} {U}_{D C} ω ( {C}_{1} + {C}_{2} ) {Im}_{3 h} \{ {u}_{C 2} - {u}_{C 1} \} ,$$
wherein U_{DC} is the DC link voltage, ω is a fundamental frequency of the output voltage, M is the modulation index, C₁ and C₂ are capacitances forming the DC link halves, Im₃ₕ is a function for the imaginary part of a third harmonic, and u_{C1} and u_{C2} are voltages over the capacitances, respectively.

5. The method according to claim 1, comprising:
determining a magnitude of a direct third harmonic component of the voltage ripple in the rotating coordinate system; and
calculating a quadrature component of an output current or power in the rotating coordinate system based on the magnitude of the direct third harmonic component.

6. The method according to claim 5, wherein a quadrature component of the output current is calculated by using the equation:
$${I}_{q} = - \frac{5 π}{8 M} ω ( {C}_{1} + {C}_{2} ) {Re}_{3 h} \{ {u}_{C 2} - {u}_{C 1} \} ,$$
wherein ω is a fundamental frequency of the output voltage, M is the modulation index, C₁ and C₂ are capacitances forming the DC link halves, Re₃ₕ is a function for the real part of a third harmonic, and u_{C1} and u_{C2} are voltages over the capacitances, respectively.

7. The method according to claim 5, wherein a quadrature component of the output power is calculated by using the equation:
$$Q = - \frac{15 π}{32} {U}_{D C } ω ( {C}_{1} + {C}_{2} ) {Re}_{3 h} \{ {u}_{C 2} - {u}_{C 1} \} ,$$
wherein U_{DC} is the DC link voltage, ω is a fundamental frequency of the output voltage, M is the modulation index, C₁ and C₂ are capacitances forming the DC link halves, Re₃ₕ is a function for the real part of a third harmonic, and u_{C1} and u_{C2} are voltages over the capacitances, respectively.

8. The method according to claim 2, comprising:
determining a magnitude of a direct third harmonic component of the voltage ripple in the rotating coordinate system; and
calculating a quadrature component of an output current or power in the rotating coordinate system based on the magnitude of the direct third harmonic component.

9. The method according to claim 8, wherein a quadrature component of the output current is calculated by using the equation:
$${I}_{q} = - \frac{5 π}{8 M} ω ( {C}_{1} + {C}_{2} ) {Re}_{3 h} \{ {u}_{C 2} - {u}_{C 1} \} ,$$
wherein ω is a fundamental frequency of the output voltage, M is the modulation index, C₁ and C₂ are capacitances forming the DC link halves, Re₃ₕ is a function for the real part of a third harmonic, and u_{C1} and u_{C2} are voltages over the capacitances, respectively.

10. The method according to claim 8, wherein a quadrature component of the output power is calculated by using the equation:
$$Q = - \frac{15 π}{32} {U}_{D C } ω ( {C}_{1} + {C}_{2} ) {Re}_{3 h} \{ {u}_{C 2} - {u}_{C 1} \} ,$$
wherein u_{DC} is the DC link voltage, ω is a fundamental frequency of the output voltage, M is the modulation index, C₁ and C₂ are capacitances forming the DC link halves, Re₃ₕ is a function for the real part of a third harmonic, and u_{C1} and u_{C2} are voltages over the capacitances, respectively.

11. The method according to claim 3, comprising:
determining a magnitude of a direct third harmonic component of the voltage ripple in the rotating coordinate system; and
calculating a quadrature component of an output current or power in the rotating coordinate system based on the magnitude of the direct third harmonic component.

12. The method according to claim 11, wherein a quadrature component of the output current is calculated by using the equation:
$${I}_{q} = - \frac{5 π}{8 M} ω ( {C}_{1} + {C}_{2} ) {Re}_{3 h} \{ {u}_{C 2} - {u}_{C 1} \} ,$$
wherein ω is a fundamental frequency of the output voltage, M is the modulation index, C₁ and C₂ are capacitances forming the DC link halves, Re₃ₕ is a function for the real part of a third harmonic, and u_{C1} and u_{C2} are voltages over the capacitances, respectively.

13. The method according to claim 11, wherein a quadrature component of the output power is calculated by using the equation:
$$Q = - \frac{15 π}{32} {U}_{D C } ω ( {C}_{1} + {C}_{2} ) {Re}_{3 h} \{ {u}_{C 2} - {u}_{C 1} \} ,$$
wherein U_{DC} is the DC link voltage, ω is a fundamental frequency of the output voltage, M is the modulation index, C₁ and C₂ are capacitances forming the DC link halves, Re₃ₕ is a function for the real part of a third harmonic, and u_{C1} and u_{C2} are voltages over the capacitances, respectively.

14. The method according to claim 4, comprising:
determining a magnitude of a direct third harmonic component of the voltage ripple in the rotating coordinate system; and
calculating a quadrature component of an output current or power in the rotating coordinate system based on the magnitude of the direct third harmonic component.

15. The method according to claim 14, wherein a quadrature component of the output current is calculated by using the equation:
$${I}_{q} = - \frac{5 π}{8 M} ω ( {C}_{1} + {C}_{2} ) {Re}_{3 h} \{ {u}_{C 2} - {u}_{C 1} \} ,$$
wherein ω is a fundamental frequency of the output voltage, M is the modulation index, C₁ and C₂ are capacitances forming the DC link halves, Re₃ₕ is a function for the real part of a third harmonic, and u_{C1} and u_{C2} are voltages over the capacitances, respectively.

16. The method according to claim 14, wherein a quadrature component of the output power is calculated by using the equation:
$$Q = - \frac{15 π}{32} {U}_{D C } ω ( {C}_{1} + {C}_{2} ) {Re}_{3 h} \{ {u}_{C 2} - {u}_{C 1} \} ,$$
wherein U_{DC} is the DC link voltage, ω is a fundamental frequency of the output voltage, M is the modulation index, C₁ and C₂ are capacitances forming the DC link halves, Re₃ₕ is a function for the real part of a third harmonic, and u_{C1} and u_{C2} are voltages over the capacitances, respectively.

17. A device for a three-level inverter having a DC link which is divided into two halves by a neutral point, the device comprising:
processing means for:
determining a voltage ripple at the neutral point;
determining a magnitude of a third harmonic component of the voltage ripple in a rotating coordinate system that rotates synchronously with an output voltage of the inverter; and
calculating a component of an output current or power in the rotating coordinate system based on the magnitude of the third harmonic component.

18. An inverter comprising a device according to claim 17.
